(19) United States
(12) Patent Application Publication
(10) Pub. No.: US 2018/0190720 A1
(43) Pub. Date: Jul. 5, 2018

(54) TOUCH DISPLAY DEVICE

(71) Applicant: InnoLux Corporation, Miao-Li County (TW)

(72) Inventors: Jui-Jen YUEH, Miao-Li County (TW); Kuan-Feng LEE, Miao-Li County (TW)

(21) Appl. No.: 15/609,156

(22) Filed: May 31, 2017

Related U.S. Application Data
(60) Provisional application No. 62/450,106, filed on Jan. 25, 2017.
(60) Provisional application No. 62/441,579, filed on Jan. 3, 2017.

(51) Int. Cl. H01L 27/32; H03K 17/96; G06F 3/041

(52) U.S. Cl. CPC H01L 27/323; G06F 2203/04103; G06F 3/0412; H03K 17/96

(57) ABSTRACT

A touch display device is provided. The touch display device includes a substrate; a driving structure layer disposed on the substrate, wherein the driving structure layer including a first switch and a second switch; a display structure layer disposed on the driving structure layer; an insulating layer disposed on the display structure layer; and a touch structure layer disposed on the insulating layer, wherein the touch structure layer is electrically connected to the first switch, and the first switch is electrically connected to the second switch.

### CROSS REFERENCE TO RELATED APPLICATIONS

This application claims the benefit of U.S. Provisional Application No. 62/441,579 filed Jan. 3, 2017, and U.S. Provisional Application No. 62/450,106 filed Jan. 25, 2017, the entireties of which are incorporated by reference herein.

### BACKGROUND

### Field of the Invention

The disclosure relates to a touch display device, and in particular to a touch display device with switches.

### Description of the Related Art

In general, an organic light-emitting diode is a self light-emitting element that emits light by electrically exciting an organic compound. Recently, organic light-emitting diodes have received much attention and been used in flat-panel displays, TV screens, computer monitors, and portable electronic device screens. When used in displays, organic light-emitting diodes provide multiple advantages, such as a self light-emitting ability, wide viewing angle, and higher brightness than flat-panel displays.

Because of advantages that include having a low production cost, having a high speed of response (about 100 times higher than liquid-crystal displays (LCDs)), being power-saving, having a wide range of operating temperatures, and being lightweight, thin film transistor-organic light-emitting diode (TFT-OLED) displays have entered the mainstream of development in the market. There are two main methods for manufacturing TFT-OLED displays: One is a technique that applies a low temperature poly-silicon (LTPS) thin film transistor, and the other one is a technique that applies a metal oxide thin film transistor.

However, existing organic light-emitting diode displays are not satisfactory in every respect. Therefore, an organic light-emitting diode display that may further improve the electrostatic discharge (ESD) protection ability and the applicability of the touch display device is still required in the industry.

### BRIEF SUMMARY OF THE INVENTION

The present disclosure provides a touch display device, including: a substrate; a driving structure layer disposed on the substrate, wherein the driving structure layer including a first switch and a second switch; a display structure layer disposed on the driving structure layer; an insulating layer disposed on the display structure layer; and a touch structure layer disposed on the insulating layer, wherein the touch structure layer is electrically connected to the first switch, and the first switch is electrically connected to the second switch.

A detailed description is given in the following embodiments with reference to the accompanying drawings.

### BRIEF DESCRIPTION OF THE DRAWINGS

The disclosure may be more fully understood by reading the subsequent detailed description and examples with references made to the accompanying drawings, wherein:

FIG. 1A is a cross-sectional view of a touch display device in accordance with some embodiments of the present disclosure;

FIG. 1B is a top view of a touch display device in accordance with some embodiments of the present disclosure;

FIG. 1C is a top view of a touch display device in accordance with some embodiments of the present disclosure;

FIG. 1D is an equivalent circuit diagram of a touch display device in accordance with some embodiments of the present disclosure;

FIG. 1E is an equivalent circuit diagram of a touch display device in accordance with some embodiments of the present disclosure;

FIG. 2A is a cross-sectional view of a touch display device in accordance with some embodiments of the present disclosure;

FIG. 2B is an equivalent circuit diagram of a touch display device in accordance with some embodiments of the present disclosure;

FIG. 2C is an equivalent circuit diagram of a touch display device in accordance with some embodiments of the present disclosure;

FIG. 3A is a cross-sectional view of a touch display device in accordance with some embodiments of the present disclosure;

FIG. 3B is an equivalent circuit diagram of a touch display device in accordance with some embodiments of the present disclosure;

FIG. 3C is an equivalent circuit diagram of a touch display device in accordance with some embodiments of the present disclosure;

FIG. 4A is a cross-sectional view of a touch display device in accordance with some embodiments of the present disclosure;

FIG. 4B is a cross-sectional view of a touch display device in accordance with some embodiments of the present disclosure;

FIG. 5A is a cross-sectional view of a touch display device in accordance with some embodiments of the present disclosure;

FIG. 5B is a top view of a touch display device in accordance with some embodiments of the present disclosure;

FIG. 5C is an equivalent circuit diagram of a touch display device in accordance with some embodiments of the present disclosure;

FIG. 5D is an equivalent circuit diagram of a touch display device in accordance with some embodiments of the present disclosure; and

FIG. 6 is a cross-sectional view of a touch display device in accordance with some embodiments of the present disclosure.

### DETAILED DESCRIPTION OF THE INVENTION

The touch display device of the present disclosure is described in detail in the following description. In the following detailed description, for purposes of explanation, numerous specific details and embodiments are set forth in order to provide a thorough understanding of the present disclosure. The specific elements and configurations described in the following detailed description are set forth in order to clearly describe the present disclosure. It will be apparent, however, that the exemplary embodiments set forth herein are used merely for the purpose of illustration, and the inventive concept may be embodied in various forms without being limited to those exemplary embodiments. In addition, the drawings of different embodiments may use like and/or corresponding numerals to denote like and/or corresponding elements in order to clearly describe the present disclosure. However, the use of like and/or corresponding numerals in the drawings of different embodiments does not suggest any correlation between different embodiments. In addition, in this specification, expressions such as “first material layer disposed on/over a second material layer”, may indicate the direct contact of the first material layer and the second material layer, or it may indicate a non-contact state with one or more intermediate layers between the first material layer and the second material layer. In the above situation, the first material layer may not be in direct contact with the second material layer.

In addition, in this specification, relative expressions are used. For example, “lower”, “bottom”, “higher” or “top” are used to describe the position of one element relative to another. It should be appreciated that if a device is flipped upside down, an element that is “lower” will become an element that is “higher”.

The term “about” typically means +/−20% of the stated value, more typically +/−10% of the stated value, more typically +/−5% of the stated value, more typically +/−3% of the stated value, more typically +/−2% of the stated value, more typically +/−1% of the stated value and even more typically +/−0.5% of the stated value. The stated value of the present disclosure is an approximate value. When there is no specific description, the stated value includes the meaning of “about”.

It should be understood that, although the terms first, second, third etc. may be used herein to describe various elements, components, regions, layers, portions and/or sections, these elements, components, regions, layers, portions and/or sections should not be limited by these terms. These terms are only used to distinguish one element, component, region, layer, portion or section from another element, component, region, layer, portion or section. Thus, a first element, component, region, layer, portion or section discussed below could be termed a second element, component, region, layer, portion or section without departing from the teachings of the present disclosure. Unless defined otherwise, all technical and scientific terms used herein have the same meaning as commonly understood by one of ordinary skill in the art to which this disclosure belongs.

This description of the exemplary embodiments is intended to be read in connection with the accompanying drawings, which are to be considered part of the entire written description. The drawings are not drawn to scale. In addition, structures and devices are shown schematically in order to simplify the drawing.

In the description, relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

The term “substrate” is meant to include devices formed within a transparent substrate and the layers overlying the transparent substrate. All transistor element needed may be already formed over the substrate. However, the substrate is represented with a flat surface in order to simplify the drawing. The term “substrate surface” is meant to include the uppermost exposed layers on a transparent substrate, such as an insulating layer and/or metallurgy lines.

In some embodiments of the present disclosure, the touch structure layer of the touch display device is electrically connected to the first switch, and the first switch is electrically connected to the second switch. In addition, each of the first switch and the second switch may be a diode or a transistor. The two switches may be combined to serve as a variety of function units such as electrostatic discharge (ESD) protection, demultiplexer, or any other suitable function units. Thereby, the electrostatic discharge (ESD) protection ability and the applicability of the touch display device may be further improved.

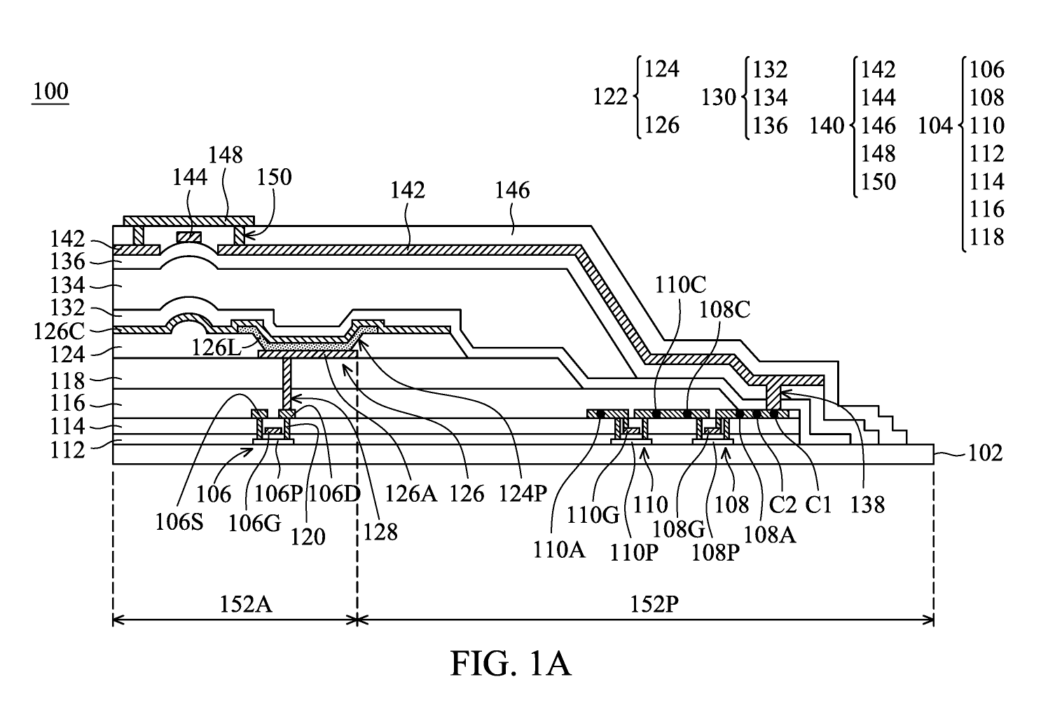

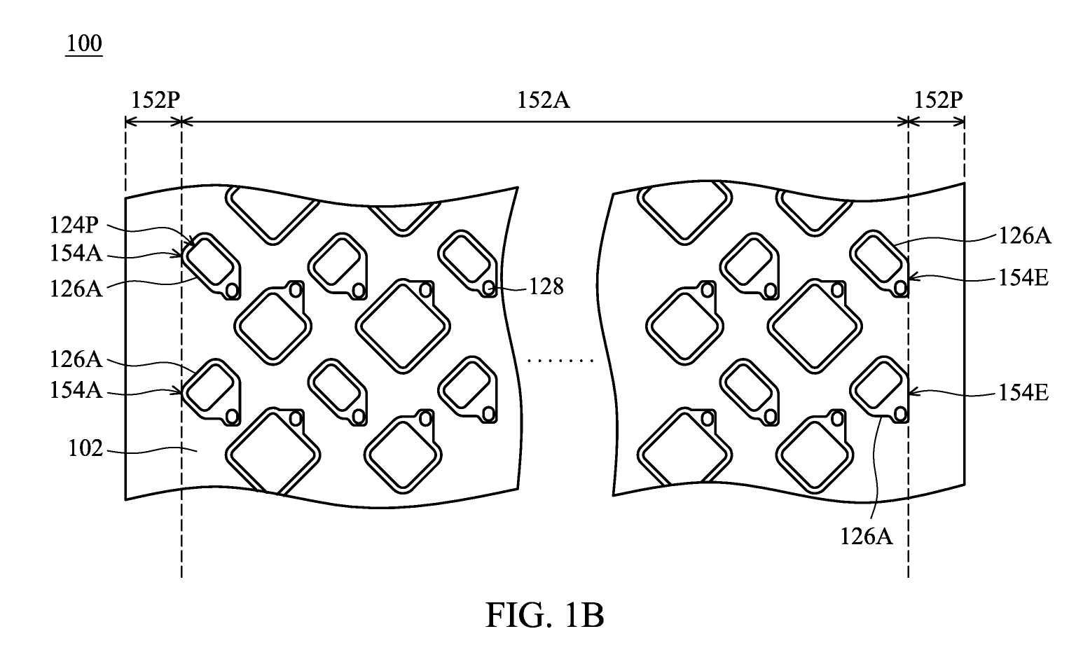

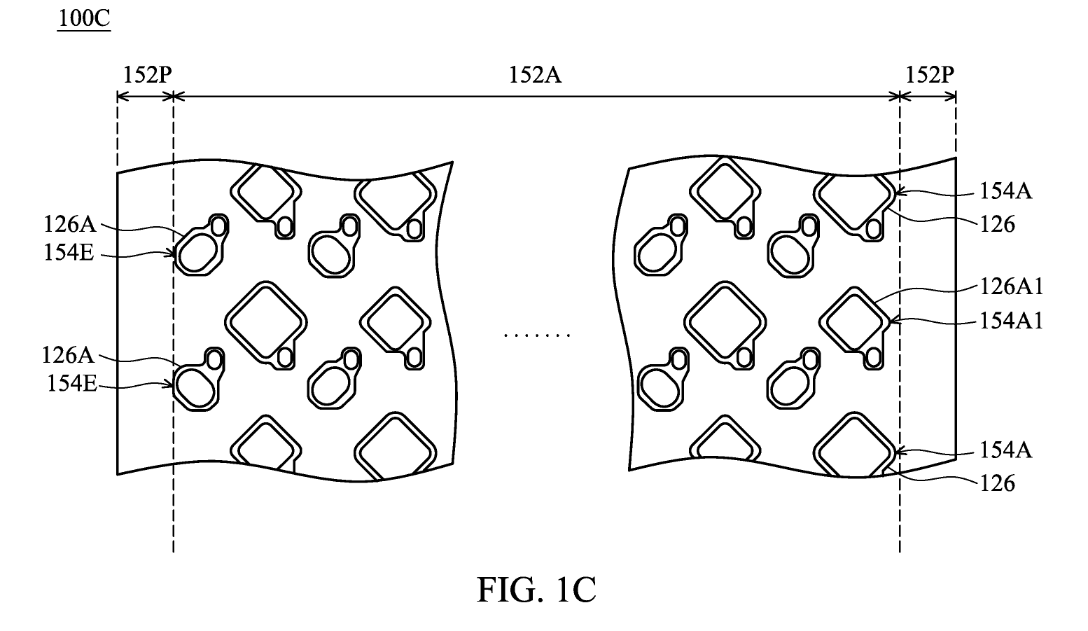

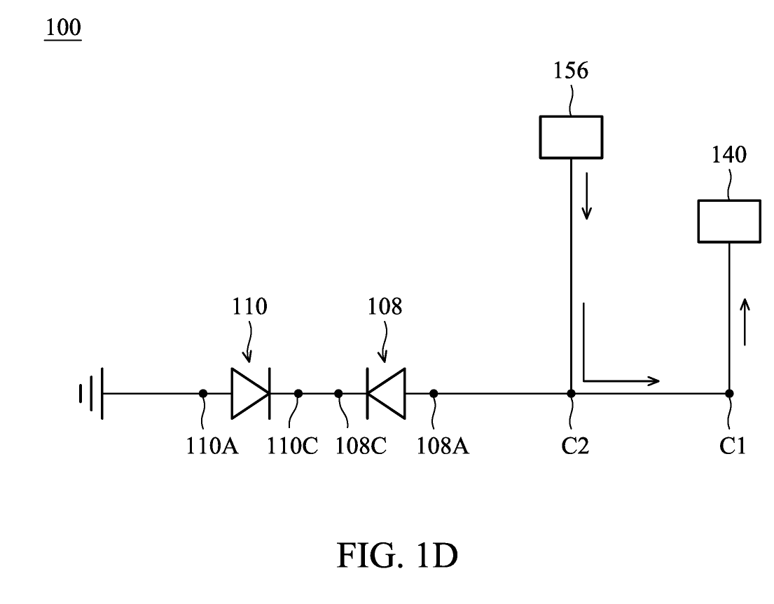

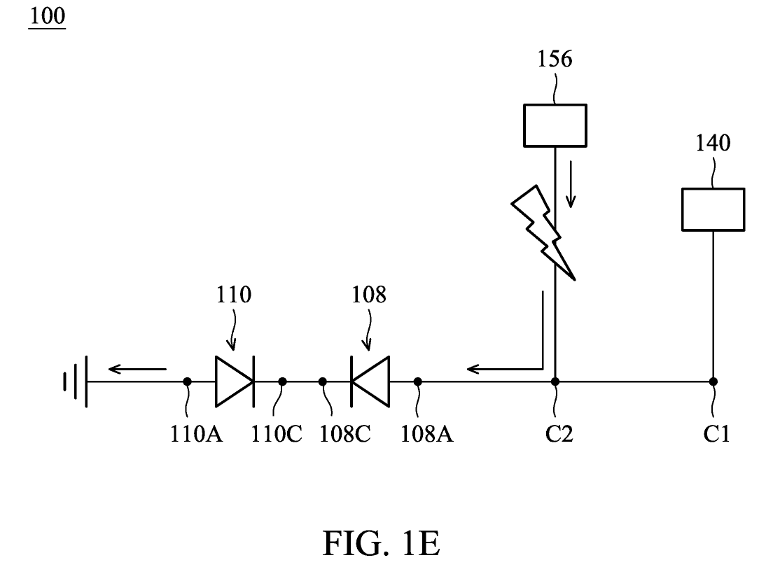

FIG. 1A is a cross-sectional view of a touch display device 100 in accordance with some embodiments of the present disclosure. As shown in FIG. 1A, in accordance with some embodiments, the touch display device 100 includes a substrate 102, and the substrate 102 may include a transparent substrate and may be a rigid substrate or flexible substrate and, for example, a glass substrate, a ceramic substrate, a plastic substrate, or any other suitable substrate. The plastic substrate may include material such as polyimide (PI), polycarbonate (PC), or polyethylene terephthalate (PET).

Still referring to FIG. 1A, the touch display device 100 further includes a driving structure layer 104 disposed on the substrate 102. As shown in FIG. 1A, the driving structure layer 104 includes a driving switch 106, a first switch 108 and a second switch 110. In some embodiments of the present disclosure, the driving switch 106 is a transistor, and the first switch 108 and the second switch 110 are diodes.

In addition, as shown in FIG. 1A, the driving structure layer 104 further includes a gate insulating layer 112 disposed on the substrate 102, an insulating layer 114 disposed on the gate insulating layer 112, an insulating layer 116 disposed on the insulating layer 114, and a planar layer 118 disposed on the insulating layer 116. In addition, as shown in FIG. 1A, the driving switch 106, the first switch 108 and the second switch 110 are disposed in/on the gate insulating layer 112 and the insulating layer 114, and are covered by the insulating layer 116.

In particular, as shown in FIG. 1A, a semiconductor layer 106P, a semiconductor layer 108P and a semiconductor layer 110P are formed on the substrate 102. The materials of semiconductor layer 106P, the semiconductor layer 108P and the semiconductor layer 110P may include silicon, germanium; a compound semiconductor which may include gallium nitride (GaN), silicon carbide, gallium arsenide, gallium phosphide, indium phosphide, indium arsenide and/or indium antimonide; an alloy semiconductor which may include SiGe alloy, GaAsP alloy, AlInAs alloy, AlGaAs alloy, GalnAs alloy, GaInP alloy and/or GaInAsP alloy; or a combination thereof.

Still referring to FIG. 1A, the gate insulating layer 112 covers the semiconductor layer 106P, the semiconductor layer 108P and the semiconductor layer 110P. The material of the gate insulating layer 112 may include, but is not limited to, silicon oxide, silicon nitride, silicon oxynitride, high-k material, any other suitable dielectric material, or a combination thereof. The high-k material may include, but is not limited to, metal oxide, metal nitride, metal silicide, transition metal oxide, transition metal nitride, transition metal silicide, transition metal oxynitride, metal aluminate, zirconium silicate, zirconium aluminate. For example, the material of the high-k material may include, but is not limited to, LaO, AlO, ZrO, TiO, Ta₂O₅, Y₂O₃, SrTiO₃(STO), BaTiO₃(BTO), BaZrO, HfO₂, HfO₃, HfZrO, HfLaO, HfSiO, HfSiON, LaSiO, AlSiO, HfTaO, HfTiO, HfTaTiO, HfAlON, (Ba,Sr)TiO₃(BST), Al₂O₃, any other suitable high-k dielectric material, or a combination thereof. The gate insulating layer 112 may be formed by chemical vapor deposition or spin-on coating. The chemical vapor deposition may include, but is not limited to, low pressure chemical vapor deposition (LPCVD), low temperature chemical vapor deposition (LTCVD), rapid thermal chemical vapor deposition (RTCVD), plasma enhanced chemical vapor deposition (PECVD), atomic layer deposition (ALD), or any other suitable method.

Still referring to FIG. 1A, a gate electrode 106G, a gate electrode 108G, and a gate electrode 110G are formed on the gate insulating layer 112. In particular, the gate electrode 106G is disposed corresponding to the semiconductor layer 106P, the gate electrode 108G is disposed corresponding to the semiconductor layer 108P, and the gate electrode 110G is disposed corresponding to the semiconductor layer 110P.

The material of the gate electrode 106G, the gate electrode 108G, and the gate electrode 110G may include, but is not limited to, one or more metal, conductive metal oxide, or a combination thereof. The metal may include, but is not limited to, copper, aluminum, molybdenum, tungsten, titanium, tantalum, platinum, or hafnium. In some embodiments of the present disclosure, the gate electrode 106G, the gate electrode 108G, and the gate electrode 110G may include three-layered structure such as Mo/Al/Mo, Ti/Al/Ti or a multilayered structure including copper and alloy. The conductive metal oxide may include, but is not limited to, ruthenium oxide or indium tin oxide. The gate electrode 106G, the gate electrode 108G, and the gate electrode 110G may be formed by the previously described chemical vapor deposition (CVD), sputtering, resistive thermal evaporation, electron beam evaporation, or any other suitable methods.

Still referring to FIG. 1A, the insulating layer 114 covers the gate electrode 106G, the gate electrode 108G, and the gate electrode 110G. The material of the insulating layer 114 may include, but is not limited to, silicon nitride, silicon oxide, or silicon oxynitride. The insulating layer 114 may be formed by chemical vapor deposition or spin-on coating. The chemical vapor deposition may include, but is not limited to, low pressure chemical vapor deposition (LPCVD), low temperature chemical vapor deposition (LTCVD), rapid thermal chemical vapor deposition (RTCVD), plasma enhanced chemical vapor deposition (PECVD), atomic layer deposition (ALD), or any other suitable method.

Still referring to FIG. 1A, a source electrode 106S and a drain electrode 106D are disposed over the insulating layer 114 and are disposed at opposite sides of the semiconductor layer 106P or the gate electrode 106G, respectively. The source electrode 106S is electrically connected to the semiconductor layer 106P at one side of the gate electrode 106G through a contact via 120. The drain electrode 106D is electrically connected to the semiconductor layer 106P at another side of the gate electrode 106G through another contact via 120.

The source electrode 106S and drain electrode 106D may include, but is not limited to, copper, aluminum, molybdenum, tungsten, gold, cobalt, nickel, platinum, titanium, iridium, rhodium, an alloy thereof, a combination thereof, or any other conductive material. In other embodiments, the source electrode 106S and drain electrode 106D includes a metal oxide material. The source electrode 106S and drain electrode 106D may include any conductive material. The material of the source electrode 106S and drain electrode 106D may be formed by chemical vapor deposition (CVD), sputtering, resistive thermal evaporation, electron beam evaporation, or any other suitable method.

As shown in FIG. 1A, the driving switch 106 includes the semiconductor layer 106P, the gate electrode 106G disposed over the semiconductor layer 106P, the source electrode 106S and the drain electrode 106D electrically connected to the semiconductor layer 106P at opposite sides of the gate electrode 106G, respectively.

Still referring to FIG. 1A, a first electrode 108A and a second electrode 108C are disposed over the insulating layer 114 and are disposed at opposite sides of the semiconductor layer 108P or the gate electrode 108G, respectively. The first electrode 108A is electrically connected to the semiconductor layer 108P at one side of the gate electrode 108G through a contact via 120. The second electrode 108C is electrically connected to the semiconductor layer 108P at another side of the gate electrode 108G through another contact via 120.

In addition, the first electrode 108A is electrically connected to the gate electrode 108G, whereas the second electrode 108C is electrically isolated from the gate electrode 108G.

The first electrode 108A and second electrode 108C may include, but is not limited to, copper, aluminum, molybdenum, tungsten, gold, cobalt, nickel, platinum, titanium, iridium, rhodium, an alloy thereof, a combination thereof, or any other conductive material. In other embodiments, the first electrode 108A and second electrode 108C includes a metal oxide material. The first electrode 108A and second electrode 108C may include any conductive material. The material of the first electrode 108A and second electrode 108C may be formed by chemical vapor deposition (CVD), sputtering, resistive thermal evaporation, electron beam evaporation, or any other suitable method.

As shown in FIG. 1A, the first switch 108 includes the semiconductor layer 108P, the gate electrode 108G disposed over the semiconductor layer 108P, the first electrode 108A and the second electrode 108C electrically connected to the semiconductor layer 108P at opposite sides of the gate electrode 108G, respectively.

Still referring to FIG. 1A, a first electrode 110A and a second electrode 110C are disposed over the insulating layer 114 and are disposed at opposite sides of the semiconductor layer 110P or the gate electrode 110G, respectively. The first electrode 110A is electrically connected to the semiconductor layer 110P at one side of the gate electrode 110G through a contact via 120. The second electrode 110C is electrically connected to the semiconductor layer 110P at another side of the gate electrode 110G through another contact via 120.

In addition, the first electrode 110A is electrically connected to the gate electrode 110G, whereas the second electrode 110C is electrically isolated from the gate electrode 110G.

The first electrode 110A and second electrode 110C may include, but is not limited to, copper, aluminum, molybdenum, tungsten, gold, cobalt, nickel, platinum, titanium, iridium, rhodium, an alloy thereof, a combination thereof, or any other conductive material. In other embodiments, the first electrode 110A and second electrode 110C includes a metal oxide material. The first electrode 110A and second electrode 110C may include any conductive material. The material of the first electrode 110A and second electrode 110C may be formed by chemical vapor deposition (CVD), sputtering, resistive thermal evaporation, electron beam evaporation, or any other suitable method.

As shown in FIG. 1A, the second switch 110 includes the semiconductor layer 110P, the gate electrode 110G disposed over the semiconductor layer 110P, the first electrode 110A and the second electrode 110C electrically connected to the semiconductor layer 110P at opposite sides of the gate electrode 110G, respectively.

In some embodiments, the materials of the source electrode 106S, drain electrode 106D, first electrode 108A, second electrode 108C, first electrode 110A and second electrode 110C may be the same, and the source electrode 106S, drain electrode 106D, first electrode 108A, second electrode 108C, first electrode 110A and second electrode 110C may be formed by the same deposition steps. However, in other embodiments, the source electrode 106S, drain electrode 106D, first electrode 108A, second electrode 108C, first electrode 110A and second electrode 110C may be formed by different deposition steps, and the materials of the source electrode 106S, drain electrode 106D, first electrode 108A, second electrode 108C, first electrode 110A and second electrode 110C may be different from each other.

In addition, in some embodiments of the present disclosure, as shown in FIG. 1A, the second electrode 108C is electrically connected to the second electrode 110C. In some embodiments of the present disclosure, as shown in FIG. 1A, the second electrode 108C and the second electrode 110C are the same electrode. However, the embodiments of the present disclosure are not limited thereto.

Still referring to FIG. 1A, the driving structure layer 104 further includes the insulating layer 116. The insulating layer 116 covers the driving switch 106, the first switch 108, the second switch 110 and the insulating layer 114. The material of the insulating layer 116 may include, but is not limited to, silicon nitride, silicon oxide, or silicon oxynitride. The insulating layer 116 may be formed by chemical vapor deposition or spin-on coating. The chemical vapor deposition may include, but is not limited to, low pressure chemical vapor deposition (LPCVD), low temperature chemical vapor deposition (LTCVD), rapid thermal chemical vapor deposition (RTCVD), plasma enhanced chemical vapor deposition (PECVD), atomic layer deposition (ALD), or any other suitable method.

Still referring to FIG. 1A, the driving structure layer 104 further includes the planar layer 118 covering a portion of the insulating layer 116. The material of the planar layer 118 may include, but is not limited to, organic insulating materials such as photosensitive resins. The planar layer 118 may be formed by chemical vapor deposition or spin-on coating. The chemical vapor deposition may include, but is not limited to, low pressure chemical vapor deposition (LPCVD), low temperature chemical vapor deposition (LTCVD), rapid thermal chemical vapor deposition (RTCVD), plasma enhanced chemical vapor deposition (PECVD), atomic layer deposition (ALD), or any other suitable method.

Still referring to FIG. 1A, the touch display device 100 further includes a display structure layer 122 disposed on the planar layer 118 of the driving structure layer 104. As shown in FIG. 1A, the display structure layer 122 includes a pixel defining layer 124 having an opening 124P, and a light-emitting unit 126 disposed corresponding to the opening 124P of the pixel defining layer 124.

In particular, as shown in FIG. 1A, the light-emitting unit 126 includes a first display electrode 126A disposed on the planar layer 118 of the driving structure layer 104, a light-emitting layer 126L disposed on the first display electrode 126A, and a second display electrode 126C disposed on the light-emitting layer 126L and on the pixel defining layer 124.

In addition, as shown in FIG. 1A, the pixel defining layer 124 covers a side portion of the first display electrode 126A, and exposes a main portion of the first display electrode 126A.

As shown in FIG. 1A, the light-emitting layer 126L is disposed in the opening 124P of the pixel defining layer 124, and disposed over the exposed main portion of the first display electrode 126A. The first display electrode 126A is electrically connected to the light-emitting layer 126L, and the light-emitting layer 126L is electrically connected to the second display electrode 126C.

In addition, in some embodiments of the present disclosure, a portion of the light-emitting layer 126L is disposed on the top surface of the pixel defining layer 124. In addition, the pixel defining layer 124 has a photo-spacer PS positioned beside the light-emitting layer 126L.

The first display electrode 126A may include, but is not limited to, copper, aluminum, molybdenum, tungsten, gold, cobalt, nickel, platinum, titanium, iridium, rhodium, an alloy thereof, a combination thereof, or any other conductive material. In other embodiments, the first display electrode 126A includes a metal oxide material. The first display electrode 126A may include any conductive material. The material of the first display electrode 126A may be formed by chemical vapor deposition (CVD), sputtering, resistive thermal evaporation, electron beam evaporation, or any other suitable method.

In some embodiments, the light-emitting layer 126L is a single-layered structure that may be one of emitting layer (EML), hole injection layer (HIL), hole transport layer (HTL), electron injection layer (EIL) and electron transport layer (ETL). In some other embodiments, the light-emitting layer 126L may be a multi-layered structure that is made up of HIL, HTL, EIL, and ETL. In some other embodiments, the light-emitting layer 126L may be made up of EML, HIL, HTL, EIL, and ETL. In some embodiments of the present disclosure, the emitting layer may include organic material and may be used in the OLED display device. In some embodiments of the present disclosure, the emitting layer may include inorganic material such as quantum dots, and may be used in the micro LED display device. In some embodiments of the present disclosure, the material of the emitting layer may be a hybrid-type material which includes organic material and inorganic material such as quantum dots, and this emitting layer may be used in the quantum dots LED (QLED) display device.

In some embodiments, the light-emitting layer 126L may be formed by CVD, spin-on coating, sputtering, evaporation or any other suitable method.

In some embodiments of the present disclosure, the second display electrode 126C may include transparent conductive materials, for example, indium tin oxide (ITO), tin oxide (SnO), indium zinc oxide (IZO), indium gallium zinc oxide (IGZO), indium tin zinc oxide (ITZO), antimony tin oxide (ATO), antimony zinc oxide (AZO), a combination thereof, or any other suitable transparent conductive oxide material.

The material of the second display electrode 126C may be formed by chemical vapor deposition (CVD), sputtering, resistive thermal evaporation, electron beam evaporation, or any other suitable method.

Furthermore, in some embodiments, the material of the pixel defining layer 124 may include acryl based rein, polyimide based resin, benzocyclobutene based resin, a combination thereof, or any other suitable material. In addition, in some embodiments, the pixel defining layer 124 may be formed by CVD, spin-on coating, sputtering, evaporation, or any other suitable method.

In some embodiments of the present disclosure, as shown in FIG. 1A, the driving structure layer 104 further includes an opening 128, and the drain electrode 106D of the driving switch 106 is electrically connected to the first display electrode 126A of the light-emitting unit 126 through the opening 128.

Still referring to FIG. 1A, the touch display device 100 further includes an insulating layer 130 disposed on the display structure layer 122. As shown in FIG. 1A, the insulating layer 130 includes an inorganic insulating layer 132 disposed on the display structure layer 122, an organic insulating layer 134 disposed on the inorganic insulating layer 132, and an inorganic insulating layer 136 disposed on the organic insulating layer 134, but not limited here.

In addition, in some embodiments of the present disclosure, as shown in FIG. 1A, a portion of the driving structure layer 104 is exposed by the display structure layer 122, and the exposed portion of the driving structure layer 104 is also covered by the insulating layer 130. In some embodiments of the present disclosure, the insulating layer 130 has an opening 138.

In some embodiments of the present disclosure, the insulating layer 130 is also referred to as a capping/package layer. In some embodiments of the present disclosure, the insulating layer 130 may only include one inorganic insulating layer, such as inorganic insulating layer 132. In these embodiments, the insulating layer 130 does not include the organic insulating layer 134 and the inorganic insulating layer 136.

The material of the inorganic insulating layer 132 may include, but is not limited to, silicon nitride, silicon oxide, or silicon oxynitride. The inorganic insulating layer 132 may be formed by chemical vapor deposition or spin-on coating. The chemical vapor deposition may include, but is not limited to, low pressure chemical vapor deposition (LPCVD), low temperature chemical vapor deposition (LTCVD), rapid thermal chemical vapor deposition (RTCVD), plasma enhanced chemical vapor deposition (PECVD), atomic layer deposition (ALD), or any other suitable method.

The material of the organic insulating layer 134 may include acryl based rein, polyimide based resin, benzocyclobutene based resin, a combination thereof, or any other suitable material. In addition, in some embodiments, the pixel defining layer 124 may be formed by CVD, spin-on coating, sputtering, evaporation, or any other suitable method.

The material of the inorganic insulating layer 136 may include, but is not limited to, silicon nitride, silicon oxide, or silicon oxynitride. The inorganic insulating layer 132 may be formed by chemical vapor deposition or spin-on coating.

Still referring to FIG. 1A, the touch display device 100 further includes a touch structure layer 140 disposed on the insulating layer 130. As shown in FIG. 1A, the touch structure layer 140 is electrically connected to the first switch 108, and the first switch 108 is electrically connected to the second switch 110.

As shown in FIG. 1A, the touch structure layer 140 includes a first touch electrode 142 and a second touch electrode 144 disposed on the insulating layer 130. The first touch electrode 142 and the second touch electrode 144 are electrically isolated from each other. As shown in FIG. 1A, the first touch electrode 142 is electrically connected to the first switch 108, and the second touch electrode 144 is electrically isolated from the first switch 108. As shown in FIG. 1A, the first touch electrode 142 of the touch structure layer 140 is electrically connected to the first switch 108 through the opening 138.

As shown in FIG. 1A, the touch structure layer 140 further includes a dielectric layer 146 (or insulating layer 146) covering the first touch electrode 142 and the second touch electrode 144, and a bridge element 148 electrically connecting two separated and adjacent first touch electrodes 142 through the opening 150 in the dielectric layer 146. However, in some other embodiments, ex. co-planner touch embodiment, the bridge element 148 may not be formed. And in this embodiment, the bridge element 148 is shown as top bridge embodiment. In another bottom bridge embodiment, the bridge element 148 could be disposed under the second touch electrode 144.

As shown in FIG. 1A, the first touch electrode 142, the second touch electrode 144 and the bridge element 148 may include transparent conductive materials, for example, indium tin oxide (ITO), tin oxide (SnO), indium zinc oxide (IZO), indium gallium zinc oxide (IGZO), indium tin zinc oxide (ITZO), antimony tin oxide (ATO), antimony zinc oxide (AZO), a combination thereof, or any other suitable transparent conductive oxide material. In another embodiment, the first touch electrode 142, the second touch electrode 144 and the bridge element 148 may include metal materials. The metal material may include, but is not limited to, copper, aluminum, molybdenum, tungsten, titanium, tantalum, platinum, or hafnium. In some embodiments of the present disclosure, the first touch electrode 142, the second touch electrode 144 and the bridge element 148 may include three-layered structure such as Mo/Al/Mo, Ti/Al/Ti or a multilayered structure including copper and alloy.

The material of the first touch electrode 142, the second touch electrode 144 and the bridge element 148 may be formed by chemical vapor deposition (CVD), sputtering, resistive thermal evaporation, electron beam evaporation, or any other suitable method.

The material of the dielectric layer 146 may include, but is not limited to, silicon nitride, silicon oxide, or silicon oxynitride. The dielectric layer 146 may be formed by chemical vapor deposition or spin-on coating. The chemical vapor deposition may include, but is not limited to, low pressure chemical vapor deposition (LPCVD), low temperature chemical vapor deposition (LTCVD), rapid thermal chemical vapor deposition (RTCVD), plasma enhanced chemical vapor deposition (PECVD), atomic layer deposition (ALD), or any other suitable method.

FIG. 1B is a top view of a touch display device 100 in accordance with some embodiments of the present disclosure. As shown in FIGS. 1A and 1B, the touch display device 100 includes an active region 152A and a peripheral region 152P. FIG. 1B shows a plurality of first display electrodes 126A on the substrate 102, a plurality of openings 128 on the substrate 102, and a plurality of openings 124P on the pixel defining layer 124. Each of the openings 128 is disposed corresponding to one first display electrode 126A, and each of the openings 124P of the pixel defining layer 124 is also disposed corresponding to one first display electrode 126A.

In order to clearly describe the present disclosure, only the substrate 102, the first display electrodes 126A, the openings 128, the opening 124P, the active region 152A and the peripheral region 152P are shown in FIG. 1B.

As shown at the left side of FIG. 1B, the outermost first display electrodes 126A have outermost apexes 154A. As shown in FIG. 1B, the connection line of the outermost apexes 154A of the outermost first display electrodes 126A defines the border of the active region 152A. As shown in FIG. 1B, the region outside the active region 152A is the peripheral region 152P. In other words, the connection line of the outermost apexes 154A of the outermost first display electrodes 126A is the interface between the active region 152A and the peripheral region 152P.

As shown at the right side of FIG. 1B, the outermost first display electrodes 126A have outermost edges 154E. As shown in FIG. 1B, the connection line of the outermost edges 154E of the outermost first display electrodes 126A defines the border of the active region 152A. In other words, the connection line of the outermost edges 154E of the outermost first display electrodes 126A is the interface between the active region 152A and the peripheral region 152P.

Therefore, the connection line of the outermost apexes 154A or the outermost edges 154E of the outermost first display electrodes 126A defines the border of the active region 152A.

FIG. 1C is a top view of a touch display device 100C in accordance with some embodiments of the present disclosure. As shown at the left side of FIG. 1C, the connection line of the outermost edges 154E of the outermost first display electrodes 126A defines the border of the active region 152A. As shown at the right side of FIG. 1C, the connection line of the outermost apexes 154A of the outermost first display electrodes 126A defines the border of the active region 152A. In addition, as shown at the right side of FIG. 1C, the first display electrodes 126A1 is not an outermost first electrodes. Therefore, the apexes 154A1 of first display electrodes 126A1 is not used to define the border of the active region 152A.

Referring back to FIG. 1A, the driving switch 106 is positioned in the active region 152A, whereas the first switch 108 and the second switch 110 are positioned in the peripheral region 152P. In addition, the first touch electrode 142 of the touch structure layer 140 is electrically connected to the first switch 108 through the opening 138 in the peripheral region 152P.

FIG. 1D is an equivalent circuit diagram of a touch display device 100 in accordance with some embodiments of the present disclosure. As shown in FIG. 1D, the touch structure layer 140 is electrically connected to the first electrode 108A of the first switch 108, the second electrode 108C of the first switch 108 is electrically connected to the second electrode 110C of the second switch 110, and the first electrode 110A of the second switch 110 is electrically connected to a ground.

In addition, the touch structure layer 140 and the first electrode 108A of the first switch 108 are electrically connected to a signal source 156. In particular, the touch structure layer 140 is electrically connected to a first connection point C1, and the signal source 156 is electrically connected to a second connection point C2 between the first connection point C1 and the first electrode 108A of the first switch 108.

As shown in FIG. 1D, the first switch 108 and the second switch 110 form a back-to-back diode, and this back-to-back diode may improve the electrostatic discharge (ESD) protection ability of the touch display device 100 and prevent the element and circuit of the touch display device 100 from being damaged by the electrostatic discharge.

In particular, as shown in FIG. 1D, the touch driving signal may be transmitted from the signal source 156 to the touch structure layer 140 as the arrow in FIG. 1D indicates.

However, as shown in FIG. 1E, when electrostatic current occurs, the back-to-back diode formed by the first switch 108 and the second switch 110 become a closed-circuit, and the electrostatic current is allowed to pass from the first electrode 108A of the first switch 108 to the first electrode 110A of the second switch 110. Therefore, the electrostatic current may be transmitted from the second connection point C2 to the ground through the back-to-back diode. Thereby, the element and circuit of the touch display device 100 may be prevented from being damaged by the electrostatic discharge (or the electrostatic current).

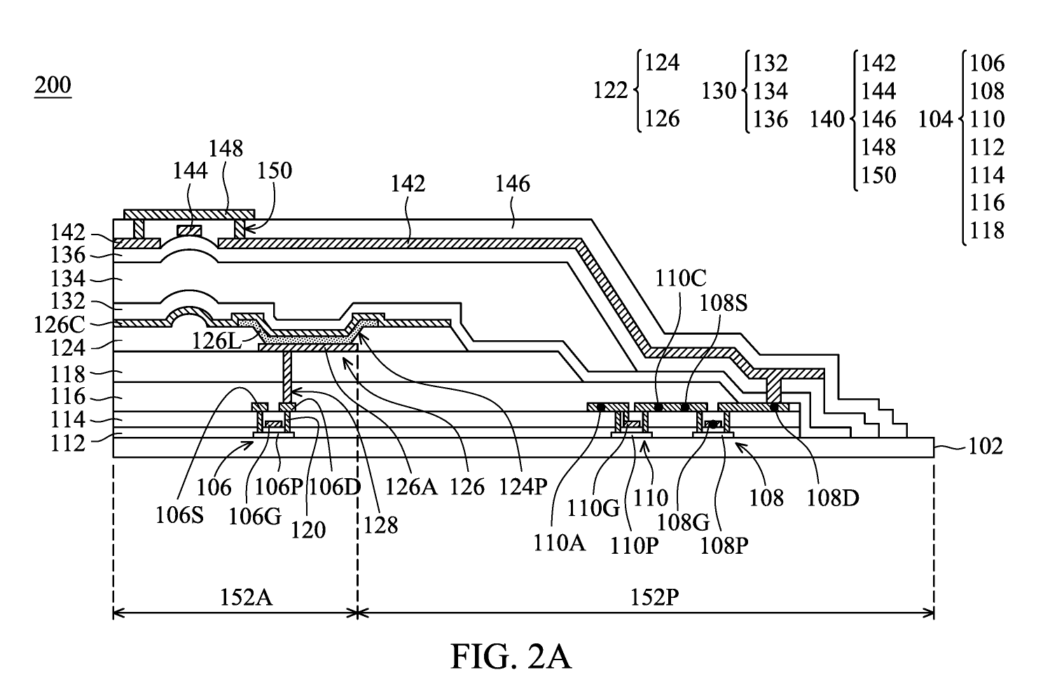

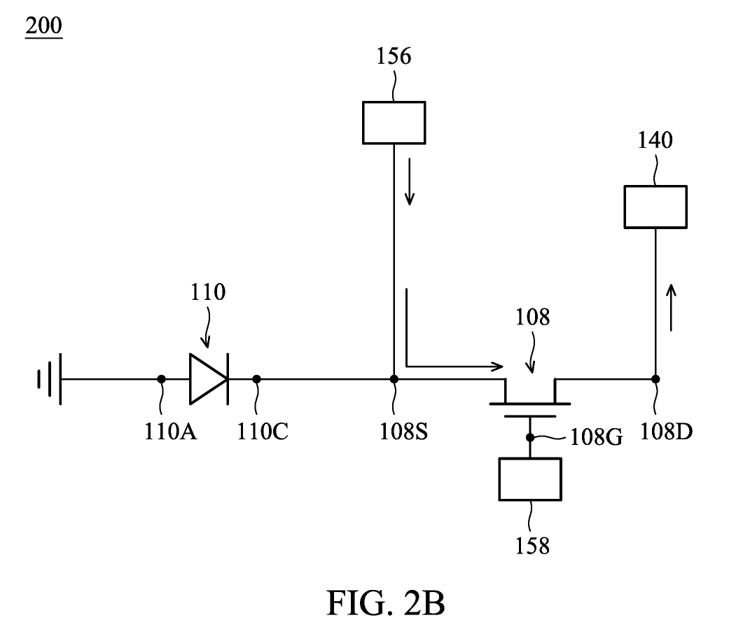

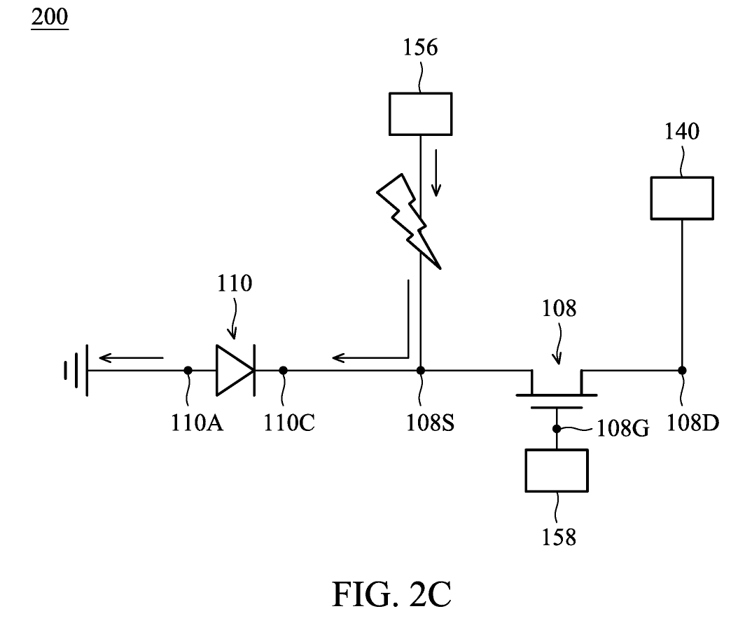

It should be noted that the exemplary embodiment set forth in FIGS. 1A-1E is merely for the purpose of illustration. In addition to the embodiment set forth in FIGS. 1A-1E, the switches could have other configuration as shown in FIGS. 2A-2C. This will be described in more detail in the following description. Therefore, the present disclosure is not limited to the exemplary embodiment shown in FIGS. 1A-1E.

Note that the same or similar elements or layers corresponding to those of the touch display device are denoted by like reference numerals. In some embodiments, the same or similar elements or layers denoted by like reference numerals have the same meaning and will not be repeated for the sake of brevity. In addition, the subsequent switches such as transistor or diode have the same or similar structures as described above, and the manufacturing process of these switches are also the same or similar to those as described above. Therefore, these will not be repeated for the sake of brevity.

FIG. 2A is a cross-sectional view of a touch display device 200 in accordance with some embodiments of the present disclosure. The difference between the embodiment shown in FIG. 1A and the embodiment shown in FIG. 2A is that the first switch 108 is a transistor, rather than a diode.

As shown in FIG. 2A, the first switch 108 includes the semiconductor layer 108P, the gate electrode 108G disposed over the semiconductor layer 108P, the source electrode 108S and the drain electrode 108D electrically connected to the semiconductor layer 108P at opposite sides of the gate electrode 108G, respectively.

In some embodiments of the present disclosure, as shown in FIG. 2A, the source electrode 108S of the first switch 108 is electrically connected to the second electrode 110C of second switch 110. As shown in FIG. 2A, the source electrode 108S of the first switch 108 and the second electrode 110C of second switch 110 are the same electrode.

FIG. 2B is an equivalent circuit diagram of a touch display device 200 in accordance with some embodiments of the present disclosure. As shown in FIGS. 2A and 2B, the touch structure layer 140 is electrically connected to the drain electrode 108D of the first switch 108, the source electrode 108S of the first switch 108 is electrically connected to the second electrode 110C of the second switch 110, the first electrode 110A of the second switch 110 is electrically connected to a ground.

In addition, as shown in FIG. 2B, the source electrode 108S of the first switch 108 and the second electrode 110C of the second switch 110 is electrically connected to the signal source 156. In addition, as shown in FIG. 2B, the gate electrode 108G is electrically connected to a touch scan signal 158.

As shown in FIG. 2B, since a transistor 108 is incorporated between the touch structure layer 140 and the signal source 156, the variety of touch driving signals may be increased accordingly. Therefore, the applicability of the touch display device 200 may be further improved.

In addition, since the second electrode 110C of the second switch 110 is electrically connected to the signal source 156, the second switch 110 may improve the electrostatic discharge (ESD) protection ability of the touch display device 100 and prevent the element and circuit of the touch display device 100 from being damaged by the electrostatic discharge.

In particular, as shown in FIG. 2B, the touch driving signal may be transmitted from the signal source 156 to the touch structure layer 140 through the first switch 108, which is a transistor, as the arrow in FIG. 2B indicates.

In some embodiments of the present disclosure, the second switch 110 is a reverse diode. According to the I-V characteristic curve of the reverse diode, at normal operating voltage, the resistance of the second switch 110 would be very large and the second switch 110 forms an open circuit. However, when a large current occurs, the resistance of the second switch 110 would decrease and the second switch 110 forms an closed-circuit. Therefore, as shown in FIG. 2C, when electrostatic current occurs, the second switch 110 become a closed-circuit, and the electrostatic current is allowed to pass from the second electrode 110C to the first electrode 110A. Therefore, the electrostatic current may be transmitted from the touch structure layer 140 to the ground through the second switch 110. Thereby, the element and circuit of the touch display device 100 may be prevented from being damaged by the electrostatic discharge (or the electrostatic current).

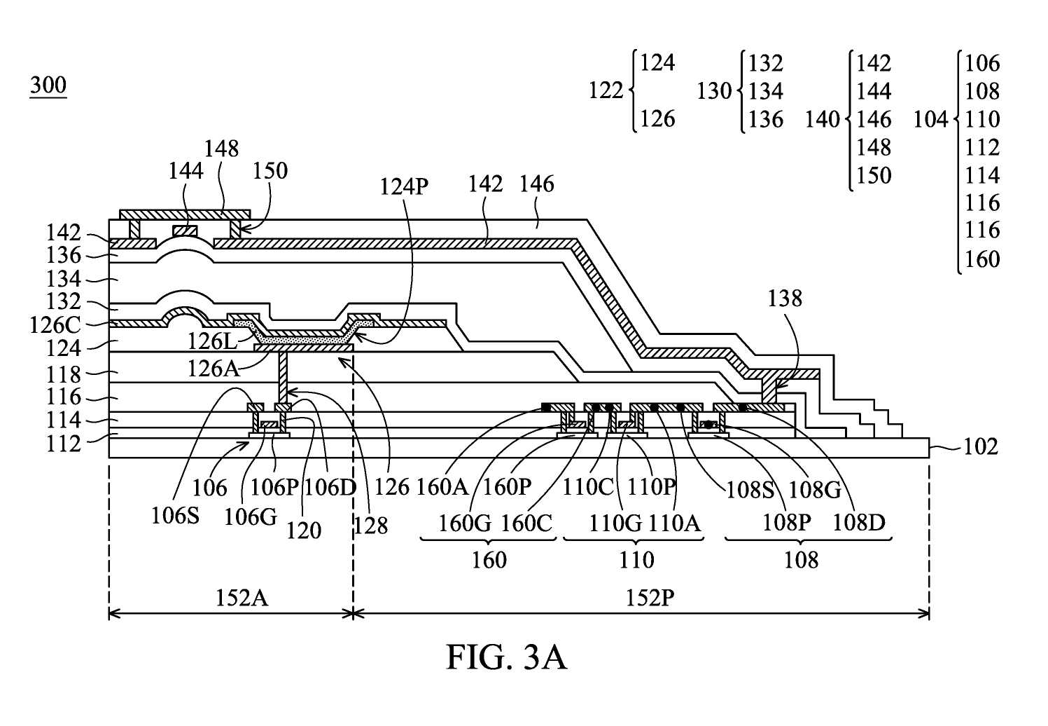

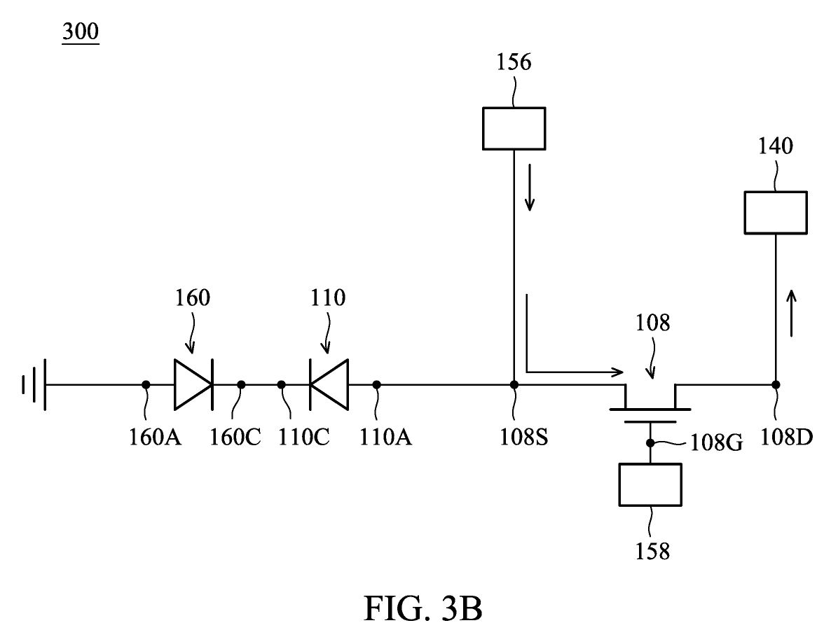

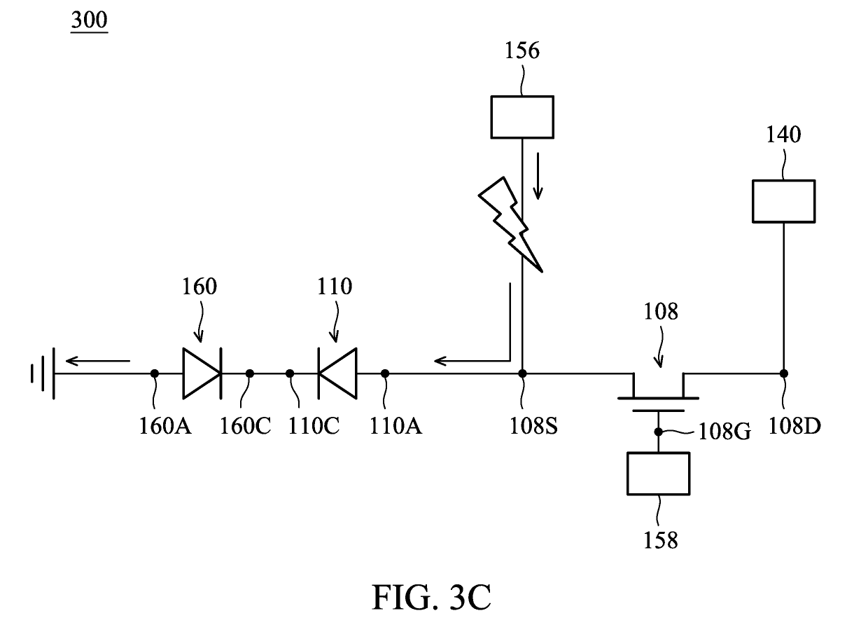

FIG. 3A is a cross-sectional view of a touch display device 300 in accordance with some embodiments of the present disclosure. The difference between the embodiment shown in FIG. 3A and the embodiment shown in FIG. 2A is that the driving structure layer 104 further includes a third switch 160, and the third switch 160 is electrically connected to the second switch 110.

As shown in FIG. 3A, the third switch 160 is a diode. As shown in FIG. 3A, the third switch 160 includes the semiconductor layer 160P, the gate electrode 160G disposed over the semiconductor layer 160P, the first electrode 160A and the second electrode 160C electrically connected to the semiconductor layer 160P at opposite sides of the gate electrode 160G, respectively. In addition, the first electrode 160A is electrically connected to the gate electrode 160G, whereas the second electrode 160C is electrically isolated from the gate electrode 160G.

Referring to FIGS. 3A and 3B, the touch structure layer 140 is electrically connected to the drain electrode 108D of the first switch 108, the source electrode 108S of the first switch 108 is electrically connected to the first electrode 110A of the second switch 110, the second electrode 110C of the second switch 110 is electrically connected to the second electrode 160C of the third switch 160, the first electrode 160A of the third switch 160 is electrically connected to a ground.

In addition, referring to FIG. 3A, the source electrode 108S of the first switch 108 and the first electrode 110A of the second switch 110 are electrically connected to the signal source 156.

As shown in FIG. 3B, since a transistor 108 is incorporated between the touch structure layer 140 and the signal source 156, the variety of touch driving signals may be increased accordingly. Therefore, the applicability of the touch display device 300 may be further improved.

As shown in FIG. 3B, the third switch 160 and the second switch 110 form a back-to-back diode, and this back-to-back diode may improve the electrostatic discharge (ESD) protection ability of the touch display device 300 and prevent the element and circuit of the touch display device 300 from being damaged by the electrostatic discharge.

In particular, as shown in FIG. 3B, the touch driving signal may be transmitted from the signal source 156 to the touch structure layer 140 through the first switch 108, which is a transistor, as the arrow in FIG. 3B indicates.

However, as shown in FIG. 3C, when electrostatic current occurs, the back-to-back diode formed by the third switch 160 and the second switch 110 become a closed-circuit, and the electrostatic current is allowed to pass from the first electrode 110A of the second switch 110 to the first electrode 160A of the third switch 160. Therefore, the electrostatic current may be transmitted from the signal source 156 to the ground through the back-to-back diode. Thereby, the element and circuit of the touch display device 300 may be prevented from being damaged by the electrostatic discharge (or the electrostatic current).

However, the embodiments of the present disclosure are not limited thereto. In some other embodiments, the second switch and/or the third switch may be transistors. Thereby, the variety of touch driving signals may be further increased. Therefore, the applicability of the touch display device may be further improved. In addition, the touch display device may include more switches in the peripheral region to increase the variety of touch driving signals and the function of the touch display device 300.

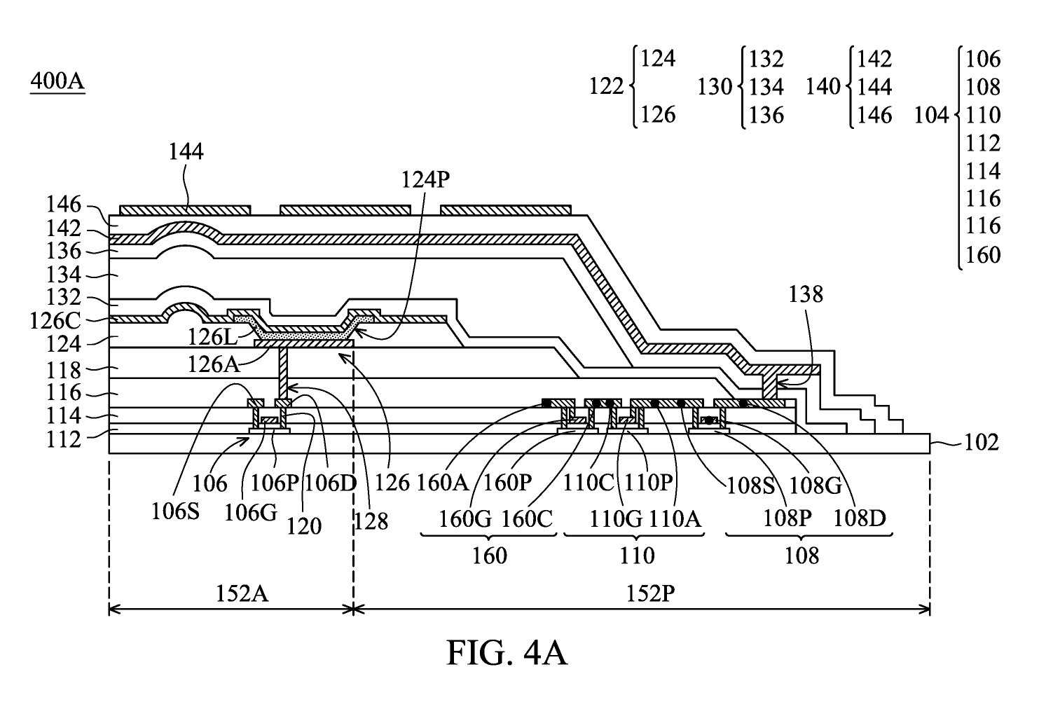

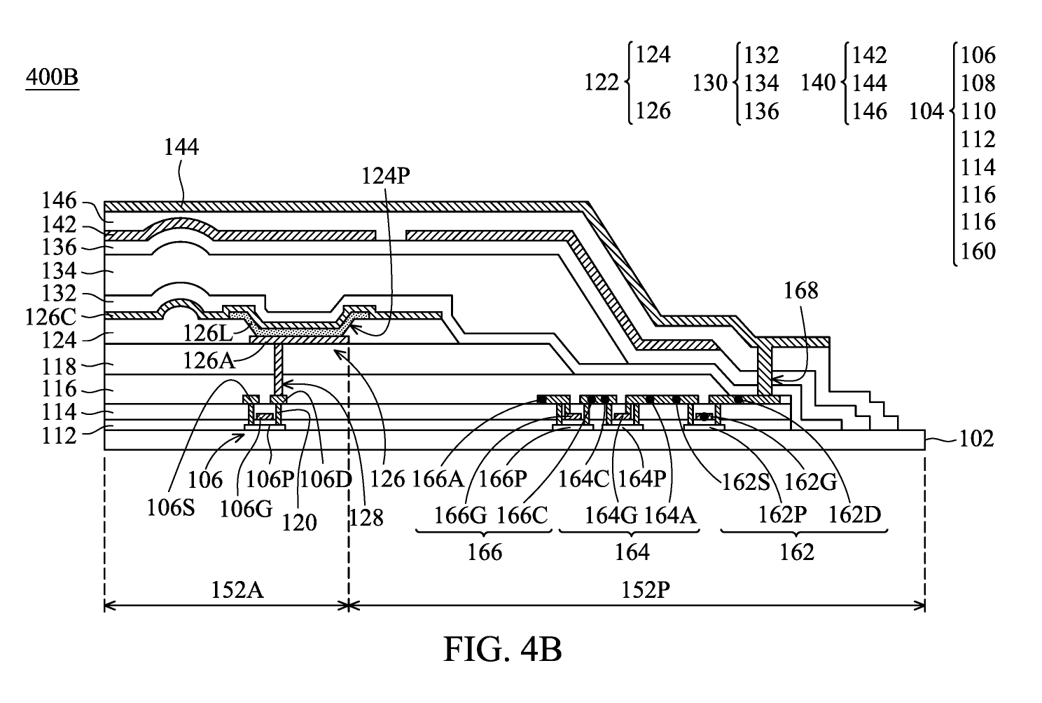

FIG. 4A is a cross-sectional view of a touch display device 400A in accordance with some embodiments of the present disclosure. The difference between the embodiment shown in FIG. 4A and the embodiment shown in FIGS. 1A-3A is that the touch structure layer 140 includes a first touch electrode 142 disposed on the insulating layer 130, a dielectric layer 146 disposed on the first touch electrode 142, and a second touch electrode 144 disposed on the dielectric layer 146. In addition, referring to FIG. 4A, the first touch electrode 142 is electrically connected to the first switch 108. The pattern of the first touch electrode 142, and the second touch electrode may have same or different pattern, and it's not limited thereto. In some embodiments of the present disclosure, the second touch electrode 144 is electrically connected to another switch, such as the fourth switch 162 shown in FIG. 4B (not shown in FIG. 4A). The another switch can be disposed at same side or different side of the touch display device.

FIG. 4B is a cross-sectional view of a touch display device 400B in accordance with some embodiments of the present disclosure. As shown in FIG. 4B, the driving structure layer 104 further includes a fourth switch 162, a fifth switch 164 and a sixth switch 166 disposed in the peripheral region 152P.

As shown in FIG. 4B, the fourth switch 162 is a transistor, the fifth switch 164 and the sixth switch 166 are diodes. As shown in FIG. 4B, the fourth switch 162 is electrically connected to the fifth switch 164, and the fifth switch 164 is electrically connected to the sixth switch 166.

In addition, as shown in FIG. 4B, the touch structure layer 140 and the insulating layer 130 have an opening 168. As shown in FIG. 4B, the second touch electrode 144 is electrically connected to the fourth switch 162 through the opening 168. The pattern of the first touch electrode 142, and the second touch electrode may have same or different pattern, and it's not limited thereto.

In particular, as shown in FIG. 4B, the fourth switch 162 includes the semiconductor layer 162P, the gate electrode 162G disposed over the semiconductor layer 162P, the first electrode 162A and the second electrode 162C electrically connected to the semiconductor layer 162P at opposite sides of the gate electrode 162G, respectively.

Still referring to FIG. 4B, the fifth switch 164 includes the semiconductor layer 164P, the gate electrode 164G disposed over the semiconductor layer 164P, the first electrode 164A and the second electrode 164C electrically connected to the semiconductor layer 164P at opposite sides of the gate electrode 164G, respectively. In addition, the first electrode 164A is electrically connected to the gate electrode 164G, whereas the second electrode 164C is electrically isolated from the gate electrode 164G.

Still referring to FIG. 4B, the sixth switch 166 includes the semiconductor layer 166P, the gate electrode 166G disposed over the semiconductor layer 166P, the first electrode 166A and the second electrode 166C electrically connected to the semiconductor layer 166P at opposite sides of the gate electrode 166G, respectively. In addition, the first electrode 166A is electrically connected to the gate electrode 166G, whereas the second electrode 166C is electrically isolated from the gate electrode 166G.

As shown in FIG. 4B, the second touch electrode 144 of the touch structure layer 140 is electrically connected to the drain electrode of the fourth switch 162, the source electrode 162S of the fourth switch 162 is electrically connected to the first electrode 164A of the fifth switch 164, the second electrode 164C of the fifth switch 164 is electrically connected to the second electrode 166C of the sixth switch 166, the first electrode 166A of the sixth switch 166 is electrically connected to a ground.

In some embodiments of the present disclosure, the touch display device in FIGS. 4A and 4B are the same device, and the first switch 108, the second switch 110 and the third switch 160 are not shown in FIG. 4B, and the fourth switch 162, the fifth switch 164 and the sixth switch 166 are not shown in FIG. 4A. In this device, the first touch electrode 142 is electrically connected to the first switch 108 as shown in FIG. 4A, and the second touch electrode 144 is electrically connected to the fourth switch 162 as shown in FIG. 4B.

However, the embodiments of the present disclosure are not limited thereto. In some other embodiments, only the first touch electrode 142 is electrically connected to the first switch 108, and the second touch electrode 144 is not electrically connected to any switch. In still some other embodiments, only the second touch electrode 144 is electrically connected to the fourth switch 162, and the first touch electrode 142 is not electrically connected to any switch.

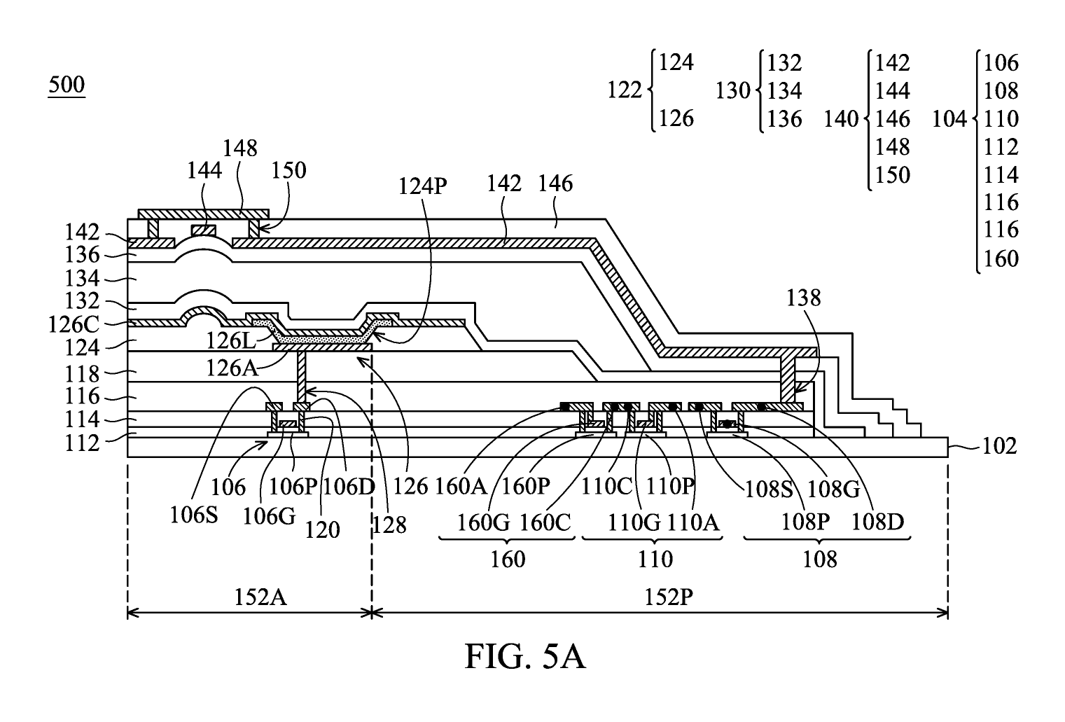

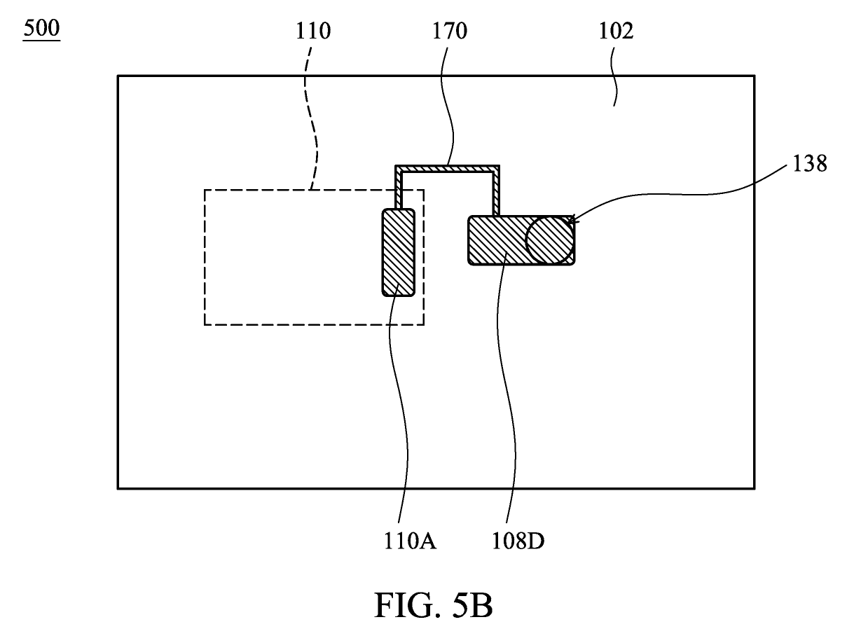

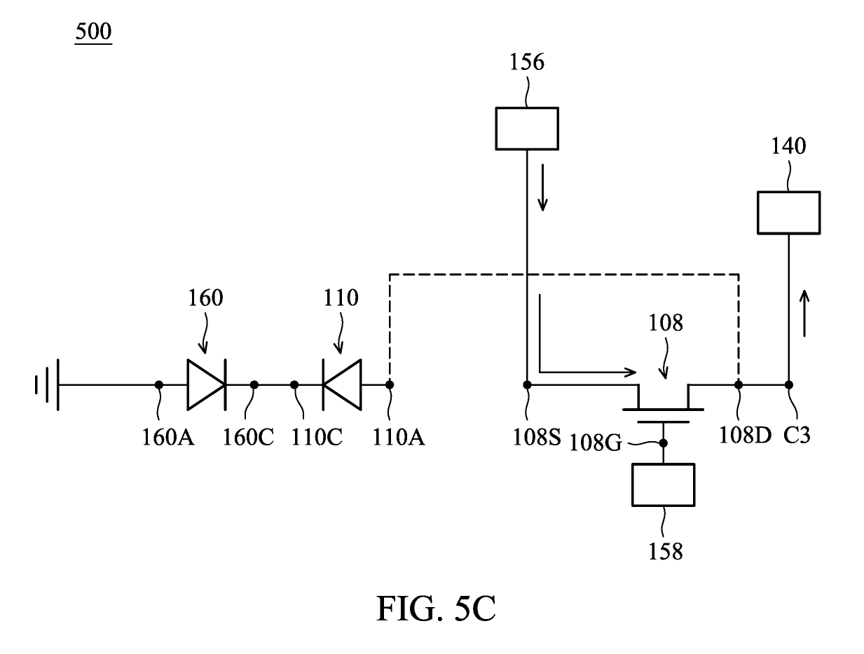

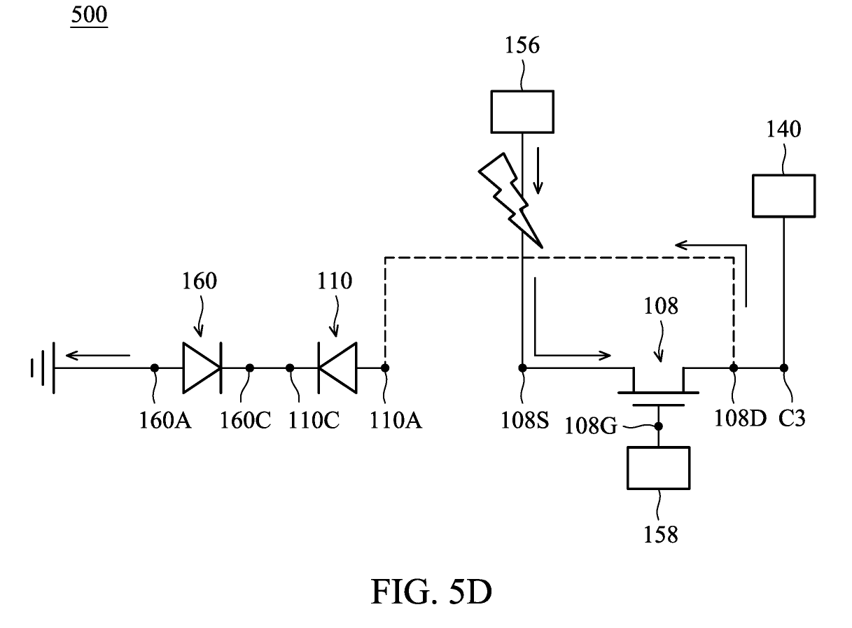

FIG. 5A is a cross-sectional view of a touch display device 500 in accordance with some embodiments of the present disclosure. FIG. 5B is a top view of a touch display device 500 in accordance with some embodiments of the present disclosure. The difference between the embodiment shown in FIGS. 5A-5B and the embodiment shown in FIG. 3A is that the first electrode 110A of the second switch 110 is electrically connected to the drain electrode 108D of the first switch 108 through a wire 170, rather than being electrically connected to the source electrode 108S of the first switch 108.

FIG. 5C is an equivalent circuit diagram of a touch display device 500 in accordance with some embodiments of the present disclosure. As shown in FIG. 5C, the touch structure layer 140 is electrically connected to a third connection point C3, which is electrically connected to the drain electrode 108D of the first switch 108. Still referring to FIG. 5C, the drain electrode 108D of the first switch 108 is electrically connected to the first electrode 110A of the second switch 110, the second electrode 110C of the second switch 110 is electrically connected to the second electrode 160C of the third switch 160, the first electrode 160A of the third switch 160 is electrically connected to a ground.

In addition, as shown in FIG. 5C, the source electrode 108S of the first switch 108 is electrically connected to the signal source 156.

As shown in FIG. 5C, since a transistor 108 is incorporated between the touch structure layer 140 and the signal source 156, the variety of touch driving signals may be increased accordingly. Therefore, the applicability of the touch display device 500 may be further improved.

As shown in FIG. 5C, the second switch 110 and the third switch 160 form a back-to-back diode, and this back-to-back diode may improve the electrostatic discharge (ESD) protection ability of the touch display device 500 and prevent the element and circuit of the touch display device 500 from being damaged by the electrostatic discharge.

In particular, as shown in FIG. 5C, the touch driving signal may be transmitted from the signal source 156 to the touch structure layer 140 through the first switch 108, which is a transistor, as the arrow in FIG. 5C indicates.

However, as shown in FIG. 5D, when electrostatic current occurs, the back-to-back diode formed by the second switch 110 and the third switch 160 become a closed-circuit, and the electrostatic current is allowed to pass from the first electrode 110A of the second switch 110 to the first electrode 160A of the third switch 160. Therefore, the electrostatic current may be transmitted from the signal source 156 to the ground through the first switch 108 and the back-to-back diode. Thereby, the element and circuit of the touch display device 500 may be prevented from being damaged by the electrostatic discharge (or the electrostatic current).

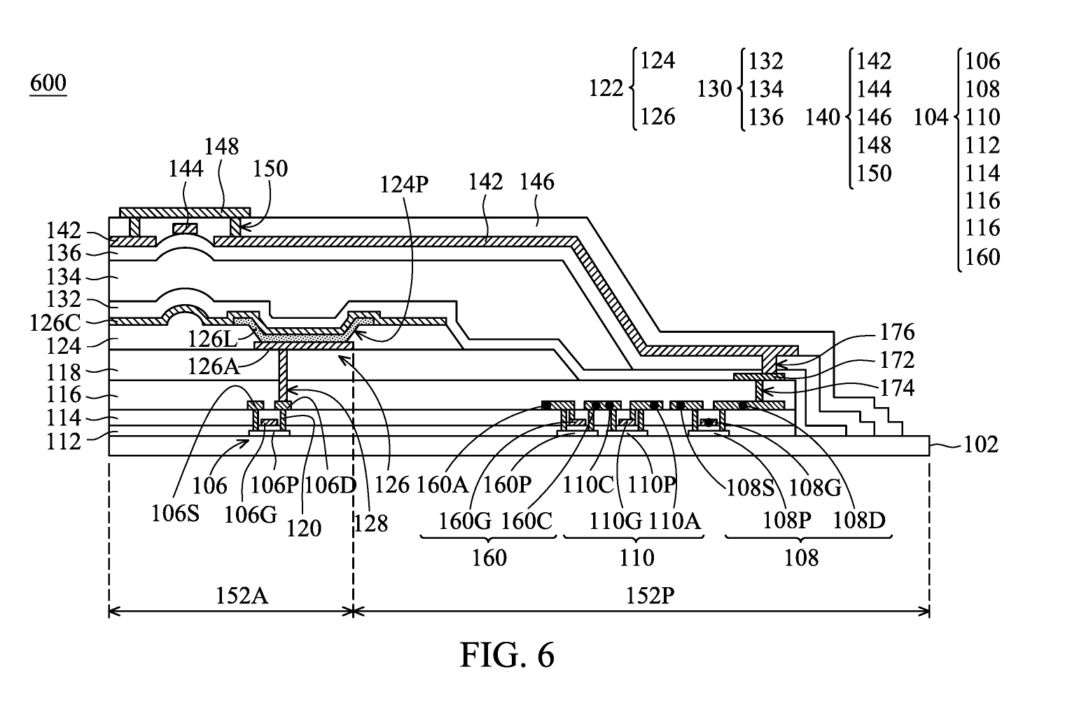

FIG. 6 is a cross-sectional view of a touch display device 600 in accordance with some embodiments of the present disclosure. The difference between the embodiment shown in FIG. 6 and the embodiment shown in FIG. 3A is that the touch display device 100 further includes a conductive layer 172 disposed on the insulating layer 116 in the peripheral region 152P.

In addition, as shown in FIG. 6, the insulating layer 116 has an opening 174, and the insulating layer 130 also has an opening 176. As shown in FIG. 6, the touch structure layer 140 is electrically connected to the conductive layer 172 through the opening 176, and the conductive layer 172 is electrically connected to the drain electrode 108D of the first switch 108 through the opening 174. In other words, the touch structure layer 140 is electrically connected to the drain electrode 108D of the first switch 108 through the opening 176, the conductive layer 172 and the opening 174.

In summary, in some embodiments of the present disclosure, the touch structure layer of the touch display device is electrically connected to the first switch, and the first switch is electrically connected to the second switch. In addition, each of the first switch and the second switch may be a diode or a transistor. The two switches may be combined to serve as a variety of function units such as electrostatic discharge (ESD) protection, demultiplexer, or any other suitable function units. Thereby, the electrostatic discharge (ESD) protection ability and the applicability of the touch display device may be further improved.

In addition, it should be noted that the drain electrode and source electrode mentioned above in the present disclosure are switchable since the definition of the drain electrode and source electrode is related to the voltage connecting thereto.

Note that the above element sizes, element parameters, and element shapes are not limitations of the present disclosure. Those skilled in the art can adjust these settings or values according to different requirements. It should be understood that the touch display device and method for manufacturing the same of the present disclosure are not limited to the configurations of FIGS. 1A to 6. The present disclosure may merely include any one or more features of any one or more embodiments of FIGS. 1A to 6. In other words, not all of the features shown in the figures should be implemented in the touch display device and method for manufacturing the same of the present disclosure.

Although some embodiments of the present disclosure and their advantages have been described in detail, it should be understood that various changes, substitutions and alterations can be made herein without departing from the spirit and scope of the disclosure as defined by the appended claims. For example, it will be readily understood by those skilled in the art that many of the features, functions, processes, and materials described herein may be varied while remaining within the scope of the present disclosure. Moreover, the scope of the present application is not intended to be limited to the particular embodiments of the process, machine, manufacture, composition of matter, means, methods and operations described in the specification. As one of ordinary skill in the art will readily appreciate from the disclosure of the present disclosure, processes, machines, manufacture, compositions of matter, means, methods, or operations, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or operations.

What is claimed is:

1. A touch display device, comprising:
a substrate;
a driving structure layer disposed on the substrate, wherein the driving structure layer comprises a first switch and a second switch;
a display structure layer disposed on the driving structure layer;
an insulating layer disposed on the display structure layer; and
a touch structure layer disposed on the insulating layer,
wherein the touch structure layer is electrically connected to the first switch, and the first switch is electrically connected to the second switch.

2. The touch display device as claimed in claim 1, wherein the first switch and the second switch are diodes.

3. The touch display device as claimed in claim 1, wherein the first switch is a transistor, and the second switch is a diode.

4. The touch display device as claimed in claim 1, wherein the driving structure layer further comprises a third switch, and the third switch is electrically connected to the second switch.

5. The touch display device as claimed in claim 4, wherein the third switch is a diode.

6. The touch display device as claimed in claim 1, wherein the insulating layer comprises a first opening, and the touch structure layer is electrically connected to the first switch through the first opening.

7. The touch display device as claimed in claim 2, wherein each of the first switch and the second switch comprises a first electrode and a second electrode,
wherein the touch structure layer is electrically connected to the first electrode of the first switch,
wherein the second electrode of the first switch is electrically connected to the second electrode of the second switch,
wherein the first electrode of the second switch is electrically connected to a ground.

8. The touch display device as claimed in claim 7, wherein the touch structure layer and the first electrode of the first switch are electrically connected to a signal source.

9. The touch display device as claimed in claim 3, wherein the first switch comprises a source electrode and a drain electrode, and the second switch comprises a first electrode and a second electrode,
wherein the touch structure layer is electrically connected to the drain electrode of the first switch,
wherein the source electrode of the first switch is electrically connected to the second electrode of the second switch,
wherein the first electrode of the second switch is electrically connected to a ground.

10. The touch display device as claimed in claim 9, wherein the source electrode of the first switch and the second electrode of the second switch is electrically connected to a signal source.

11. The touch display device as claimed in claim 5, wherein the first switch is a transistor, the first switch comprises a source electrode and a drain electrode, and each of the second switch and the third switch comprises a first electrode and a second electrode,
wherein the touch structure layer is electrically connected to the drain electrode of the first switch,
wherein the source electrode of the first switch is electrically connected to the first electrode of the second switch,
wherein the second electrode of the second switch is electrically connected to the second electrode of the third switch,
wherein the first electrode of the third switch is electrically connected to a ground.

12. The touch display device as claimed in claim 11, wherein the source electrode of the first switch and the first electrode of the second switch are electrically connected to a signal source.

13. The touch display device as claimed in claim 5, wherein the first switch is a transistor, the first switch comprises a source electrode and a drain electrode, and each of the second switch and the third switch comprises a first electrode and a second electrode,
wherein the touch structure layer is electrically connected to the drain electrode of the first switch,
wherein the drain electrode of the first switch is electrically connected to the first electrode of the second switch,
wherein the second electrode of the second switch is electrically connected to the second electrode of the third switch,
wherein the first electrode of the third switch is electrically connected to a ground.

14. The touch display device as claimed in claim 13, wherein the source electrode of the first switch is electrically connected to a signal source.

15. The touch display device as claimed in claim 1, wherein the touch structure layer comprises:
a first touch electrode disposed on the insulating layer, wherein the first touch electrode is electrically connected to the first switch;
a second touch electrode disposed on the insulating layer, wherein the second touch electrode is electrically isolated from the first touch electrode and the first switch; and
a dielectric layer covering the first touch electrode and the second touch electrode.

16. The touch display device as claimed in claim 1, wherein the driving structure layer further comprises a fourth switch, wherein the touch structure layer comprises:
a first touch electrode disposed on the insulating layer, wherein the first touch electrode is electrically connected to the first switch;
a dielectric layer disposed on the first touch electrode;
a second touch electrode disposed on the dielectric layer, wherein the second touch electrode is electrically connected to the fourth switch.

17. The touch display device as claimed in claim 16, wherein the fourth switch is a transistor, wherein the fourth switch comprises a source electrode and a drain electrode,
wherein the driving structure layer further comprises a fifth switch and a sixth switch, wherein the fifth switch and the sixth switch are diodes, wherein the fourth switch is electrically connected to the fifth switch, and the fifth switch is electrically connected to the sixth switch,
wherein each of the fifth switch and the sixth switch comprises a first electrode and a second electrode,
wherein the second touch electrode is electrically connected to the drain electrode of the fourth switch,
wherein the source electrode of the fourth switch is electrically connected to the first electrode of the fifth switch,
wherein the second electrode of the fifth switch is electrically connected to the second electrode of the sixth switch,
wherein the first electrode of the sixth switch is electrically connected to a ground.

18. The touch display device as claimed in claim 1, wherein the display structure layer comprises a light-emitting unit, wherein the light-emitting unit comprises:
a first display electrode disposed on the driving structure layer;
a light-emitting layer disposed on the first display electrode; and
a second display electrode disposed on the light-emitting layer.

19. The touch display device as claimed in claim 18, wherein the driving structure layer further comprises a seventh switch, wherein the seventh switch is a transistor, and the seventh switch comprises a source electrode and a drain electrode,
wherein the drain electrode of the seventh switch is electrically connected to the first display electrode of the light-emitting unit.

20. The touch display device as claimed in claim 19, wherein the driving structure layer further comprises a second opening,
wherein the drain electrode of the seventh switch is electrically connected to the first display electrode of the light-emitting unit through the second opening.
